(19) United States
(12) Patent Application Publication
(10) Pub. No.: US 2008/0055117 A1
(43) Pub. Date: Mar. 6, 2008

(54) CHARACTER ENTRY APPARATUS AND METHOD USING NUMERIC KEY

(76) Inventor: Kyung Ho LEE, Seoul (KR)

Correspondence Address: LADAS & PARRY LLP, 224 SOUTH MICHIGAN AVENUE, SUITE 1600, CHICAGO, IL, 60604, US

(21) Appl. No.: 11/782,775

(22) Filed: Jul. 25, 2007

(30) Foreign Application Priority Data
Aug. 31, 2006 (KR) 10-2006-0083343

(51) Int. Cl. H03K 17/94

(52) U.S. Cl. 341/23

(57) ABSTRACT

There are provided a character entry apparatus and a character entry method using numeric keys, the character entry apparatus including: a number input section having ten numeric keys of 0 to 9 for entry of a number set corresponding to a desired character; a display for displaying the character corresponding to the number set; and a controller for storing a character input table providing an arrangement of a plurality of characters each corresponding to a number set and when a number set is input through the number input section, controlling to display the corresponding character arranged in the character input table and associated with the number set through the display, the number set being formed to include a first number selected from a first number group having a plurality of numbers and a second number selected from a second number group having a plurality of numbers arranged independent of the first number group. The character entry apparatus and method may enhance the character input speed and simplify the character entry procedure.

### CROSS-REFERENCE TO RELATED APPLICATION

This application claims the benefit of Korean Patent Application No. 10-2006-83343, filed on 31 Aug. 2006, the disclosure of which is hereby incorporated herein by reference in its entirety.

### BACKGROUND OF THE INVENTION

1. Technical Field

The present invention relates to a character entry apparatus and method using numeric keys, and more particularly, to a character entry apparatus and method using numeric keys to enable more convenient international character entry with numeric keys.

2. Discussion of Related Art

With an increasing demand for information-telecommunications and development of communication and computer equipment in both hardware and software in recent years, the equipment technologies are being driven towards miniaturization, high functionality and high performance. This trend is prompting the development of equipment for more efficient and logical input/output of characters in different languages.

The information-telecommunication equipment uses 103-key computer keyboards or 12-button keypads for international character entry system.

The 103-key computer keyboard system, currently in widespread use as international character entry equipment, cannot be used for portable equipment because it is too bulky to handle. Due to its unwieldiness, the keyboard system is also problematic in being additionally associated with other equipment.

Contrarily, the 12-button keypad system is widely used for mobile phones and other portable equipment.

FIG. 1 shows a 12-button keypad layout provided in a conventional character entry system.

To enter a normal number, a user presses a key designated to the corresponding number in the same way as using the conventional number entry device for normal number entry.

For alphabetic letter entry, for example, two or three alphabetic letters are assigned to the numeric keys (buttons) as follows:

| | |
|---|---|
| 1 | QZ |
| 2 | ABC |
| 3 | DEF |
| 4 | GHK |
| 5 | JKL |
| 6 | MNO |
| 7 | PRS |
| 8 | TUV |
| 9 | WXY |

In this approach, the characters on each key are displayed in sequence depending upon the number of taps made on the particular key. For example, the user presses the “5” key twice to select the character “K” and the “7” key three times to select the character “S”.

The “3” key is pressed once for the character “D”, twice for the character “E” and so on. Pressing and holding the “3” key cycles through the characters associated with the key to display D, E, F, D, E, F and so forth. While a desired character appears, the user presses a move key (e.g., “*” key or “#” key, etc.) or holds for a predetermined period of time to enter the current character. The cursor, after the selection of the character, moves forward for the next character entry.

The entry of Korean alphabets, Hangul is done in a similar way to that of Roman alphabets. For Hangul entry, two or three Jamo (Hangul consonants and vowels) are assigned to each numeric key (button).

The above-described conventional character entry device and method used for mobile phone or the like involves the user pressing a numeric key at least three times to enter a character in English, Japanese or Korean language. To enter a word “the”, for example, the user needs to press the “8” key once, the “4” key twice and the “3” key twice, taking too much time to enter characters.

In addition, input mode switching is required to enter a number and then an alphabetic letter. To enter “3F”, the user presses the “3” key for the number “3”, changes the input mode to the alphabet input mode and presses the “3” key three times for the character “F”. Another input mode switching is required to enter a special character.

As described above, the conventional character entry method takes too much time for character entry and involves a complicated entry method.

### SUMMARY OF THE INVENTION

It is therefore an object of the present invention to provide a character entry apparatus and method using numeric keys that overcomes the problems with the conventional system.

It is another object of the present invention to provide a character entry apparatus and method using numeric keys that simplifies the entry procedure of all characters and numbers.

It is still another object of the present invention to provide a character entry apparatus and method using numeric keys that enhances the character input speed.

In accordance with an embodiment of the present invention to accomplish a part of the objects, there is provided a character entry apparatus that includes: a number input section having ten numeric keys of 0 to 9 for entry of a number set corresponding to a desired character; a display for displaying the character corresponding to the number set; and a controller for storing a character input table providing an arrangement of a plurality of characters each corresponding to a number set and when a number set is input through the number input section, controlling to display the corresponding character arranged in the character input table and associated with the number set through the display, the number set being formed to include a first number selected from a first number group having a plurality of numbers and a second number selected from a second number group having a plurality of numbers arranged independent of the first number group.

The display includes a separate display means or display space for displaying the character input table. The character input table includes at least one selected from: an alphabet input table including at least capital letters, small letters and special characters; a Hangul (Korean-language) input table including at least Hangul consonants and vowels and special characters; and a Japanese-language input table including at least 50 Hiragana/Katakana characters and special characters.

The characters arranged in the character input table include Roman alphabets, Japanese characters, Hangul alphabets, numbers, special characters or command-related characters. The controller executes a corresponding command when the character corresponding to the number set is a special command-related character. The number input section includes a keypad for portable equipment, or a keypad provided on a wireless remote controller used for electronic appliances or a wire/wireless microphone for karaoke equipment. The display includes a display device for displaying images and captions for karaoke equipment.

In accordance with another embodiment of the present invention to accomplish a part of the objects, there is provided a character entry method that includes: displaying a character input table providing an arrangement of a plurality of characters each corresponding to a number set being formed to include a first number selected from a first number group having a plurality of numbers and a second number selected from a second number group having a plurality of numbers arranged independent of the first number group; entering a number set corresponding to a desired character through a number input section with an arrangement of ten numeric keys of 0 to 9; and controlling to display the corresponding character arranged in the character input table and corresponding to the number set.

The character input table and the corresponding character displayed by an entry of the number set are displayed through different display spaces or different display devices. The character input table includes at least one selected from: an alphabet input table including at least capital letters, small letters and special characters; a Hangul (Korean-language) input table including at least Hangul consonants and vowels and special characters; or a Japanese-language input table including at least 50 Hiragana/Katakana characters and special characters.

The embodiments of the present invention may enhance the character input speed and simplify the character entry procedure.

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 shows a conventional 12-button keypad;

FIG. 2 is a block diagram of a character entry apparatus according to an embodiment of the present invention; and

FIGS. 3, 4 and 5 show examples of the character input table built in the controller of FIG. 2.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided as teaching examples of the invention. Like numbers refer to like element.

FIG. 2 is a block diagram of a character entry apparatus according to an embodiment of the present invention.

Referring to FIG. 2, the character entry apparatus according to an embodiment of the present invention includes a number input section 110, a controller 120 and a display 130.

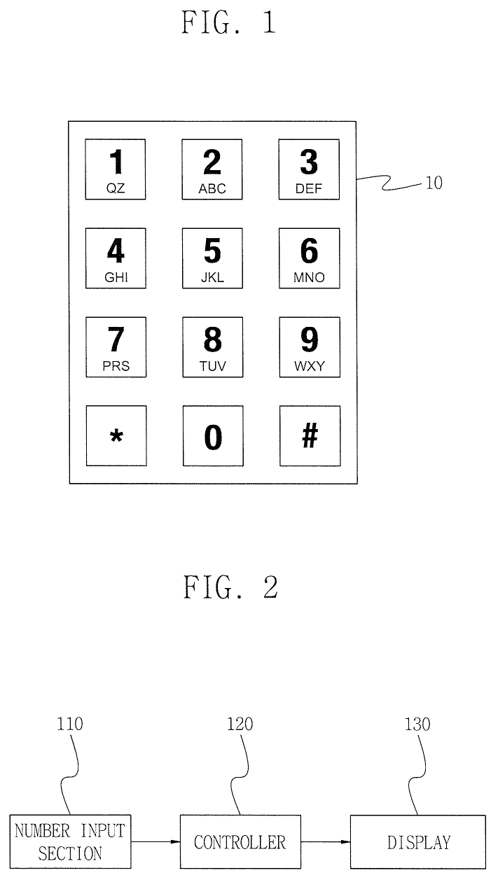

The number input section 110 has a keypad on which ten numeric keys designating 0 to 9 are arranged for entry of a number set corresponding to a desired character. The number input section 110 may have a 12-button keypad as illustrated in FIG. 1 or a 10-button keypad having numeric keys other than special characters.

The display 130 is to display the character corresponding to the number set.

The controller 120 controls the general operations for character entry. A character input table is established and stored providing a plurality of characters arranged so that each character is associated with a number set consisting of a first number selected from a first number group having a plurality of numbers and a second number selected from a second number group having a plurality of numbers arranged independent of the first number group. With a defined number set input through the number input section 110, the controller 120 controls the character arranged in the character input table and corresponding to the number set through the display 130.

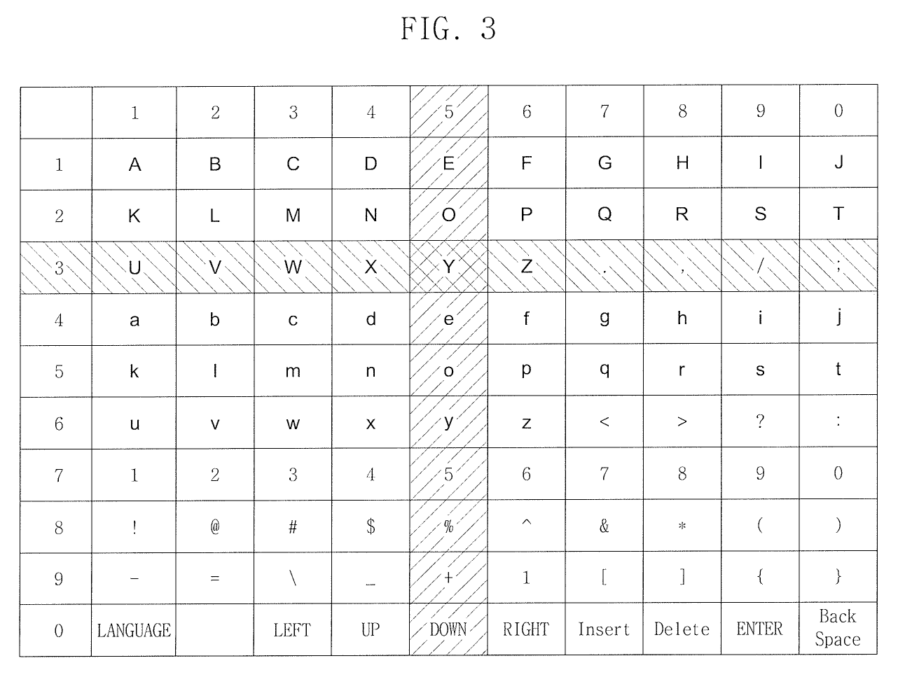

The character input table includes an alphabet input table containing at least capital letters, small letters and special characters; a Hangul (Korean-language) input table containing at least Hangul consonants and vowels and special characters; a Japanese-language input table containing at least 50 (Hiragana/Katakana) characters and special characters; and/or another foreign language input table. The examples of those are presented in FIGS. 3, 4 and 5.

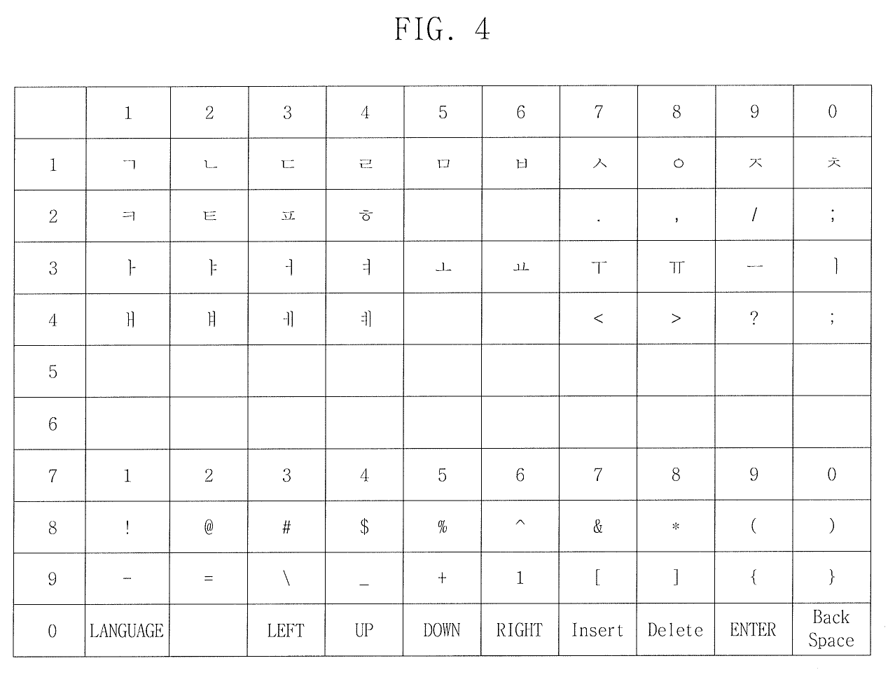

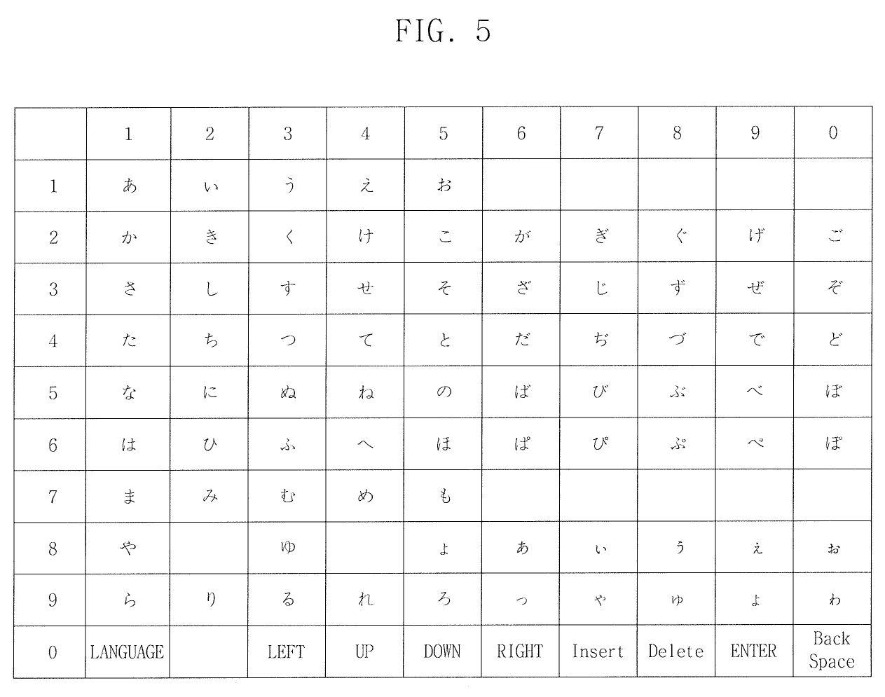

FIG. 3 shows an alphabet input table; FIG. 4 shows a Hangul input table; and FIG. 5 shows a Japanese-language input table.

The character input tables of FIGS. 3, 4 and 5 are provided as examples of the present invention and may be embodied in different arrangements according to different approaches. It is most preferred that the most frequently used characters are associated with the most accessible numeric keys. The Chinese input table or the like for other foreign languages may also be established in the same manner as known to those skilled in the art of the present invention.

The character input table may be described as follows with reference to FIG. 3.

In the character input table, the row has values ranging from 1 to 10 and the column has values ranging from 1 to 10. Each character lies where one row value meets one column value. The character input table in this case contains at most 100 characters, which may include Roman alphabets, Japanese characters, Hangul alphabets, numbers, special characters or special command-related characters. All the characters of any language, which are mostly not more than 100 in number, may be arranged in one character input table. In the character input table for a certain language that includes over 100 characters with irregularity, for example, a Chinese-language input table, the characters may be arranged in the order of radicals or most frequently used characters.

The controller 120 displays the corresponding character when the character corresponding to the number set is a desired one, and executes a corresponding command when the character corresponding to the number set is one related to a special command (e.g., Insert, Delete, Enter, etc.). For example, the controller deletes the previous character when the character corresponding to the number set is the “Delete” command.

The character input section may be used for simple text entry using numeric keys alone or for electronic appliances having a display device, mobile communication terminals and/or karaoke equipment. Particularly, the number input section 110 may include a keypad for portable equipment or a keypad provided on electronic appliances (e.g., TV, VCR, PC, etc.) or wireless remote controllers for karaoke equipment. The display 130 may include a separate display means or a separate display space for displaying the character input table. The display 130 may also include a display device for displaying images or captions for karaoke equipment.

The character input section, when used for karaoke equipment, may be used to provide the functions of selecting or searching for song titles.

The character entry method is described as follows with reference to FIG. 3.

The entry of capital letter “Y” is exemplified to describe the character entry method of the present invention.

First, the alphabet input table of FIG. 3 for character entry is displayed on the display device or the display space of the display 130. Also there may be no display of the alphabet input table which is well known or presented in a separate-volume supplement or an appendix.

In order to enter the capital letter “Y”, the user presses the “3” key to highlight the row of the number “3”, that is, activate capital letters and special characters U, V, W, X, Y, Z, ., ,, /, and ;. The character to be entered is then determined depending on the number the user selects from the list of numbers in the column. For example, the user presses the “1” key for the character “U” and the “0” key for the character “;”. Character “Y” is selected by the user's selection (pressing) of the “5” key, that is, the number set {3,5}. The user may also select the number set {4,7} to enter the small letter “g”. This method makes it possible to enter all the characters necessary for the alphabet entry.

A special command is executed when the user selects a key corresponding to the special command. Such commands are presented on the row of the number “0”. “Language” key is for the command to select a language from alphabet, Hangul or Japanese, and “Left”, “Right”, “Up” and “Down” keys are for the commands to move the cursor. “Insert”, “Delete”, “Enter” and “Back Space” keys are commands well known to those skilled in the art and will not be described.

The present invention as described above requires the user to press numeric keys no more than twice to enter one character. This provides an improvement of the conventional character entry system that complicatedly demands at least three times of pressing numeric keys for one character entry, thereby simplifying the character entry procedure. The present invention also enhances the character input speed in entering a number or a special character after a character entry, because characters, numbers and special characters are all contained in one character input table.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A character entry apparatus comprising:
a number input section having ten numeric keys of 0 to 9 for entry of a number set corresponding to a desired character;
a display for displaying the character corresponding to the number set; and
a controller for storing a character input table providing an arrangement of a plurality of characters each corresponding to a number set and when a number set is input through the number input section, controlling to display the corresponding character arranged in the character input table and associated with the number set through the display, the number set being formed to include a first number selected from a first number group having a plurality of numbers and a second number selected from a second number group having a plurality of numbers arranged independent of the first number group.

2. The character entry apparatus as claimed in claim 1, wherein the display comprises a separate display means or display space for displaying the character input table.

3. The character entry apparatus as claimed in claim 1, wherein the character input table comprises at least one selected from:
an alphabet input table including at least capital letters, small letters and special characters;
a Hangul (Korean-language) input table including at least Hangul consonants and vowels and special characters; and
a Japanese-language input table including at least 50 Hiragana/Katakana characters and special characters.

4. The character entry apparatus as claimed in claim 1, wherein the characters arranged in the character input table comprise Roman alphabets, Japanese characters, Hangul alphabets, numbers, special characters or command-related characters.

5. The character entry apparatus as claimed in claim 4, wherein the controller executes a corresponding command when the character corresponding to the number set is a special command-related character.

6. The character entry apparatus as claimed in claim 1, wherein the number input section comprises a keypad for portable equipment, or a keypad provided on a wireless remote controller used for electronic appliances or a wire/wireless microphone for karaoke equipment.

7. The character entry apparatus as claimed in claim 6, wherein the display comprises a display device for displaying images and captions for karaoke equipment.

8. A character entry method comprising:
displaying a character input table providing an arrangement of a plurality of characters each corresponding to a number set being formed to include a first number selected from a first number group having a plurality of numbers and a second number selected from a second number group having a plurality of numbers arranged independent of the first number group;
entering a number set corresponding to a desired character through a number input section with an arrangement of ten numeric keys of 0 to 9; and
controlling to display the corresponding character arranged in the character input table and corresponding to the number set.

9. The character entry method as claimed in claim 8, wherein the character input table and the corresponding character displayed by an entry of the number set are displayed through different display spaces or different display devices.

10. The character entry method as claimed in claim 8, wherein the character input table comprises at least one selected from:
an alphabet input table including at least capital letters, small letters and special characters;
a Hangul (Korean-language) input table including at least Hangul consonants and vowels and special characters; or
a Japanese-language input table including at least 50 Hiragana/Katakana characters and special characters.
